(19) United States
(12) Patent Application Publication
(10) Pub. No.: US 2026/0229271 A1
(43) Pub. Date: Aug. 6, 2026

(54) SCHEDULING DEVICE AND AN OPERATION METHOD FOR A MEMORY DEVICE USING A MULTI-CLOCK COMMAND

(71) Applicant: SK hynix Inc., Gyeonggi-do (KR)

(72) Inventor: Dong-Gun KIM, Gyeonggi-do (KR)

(21) Appl. No.: 19/241,383

(22) Filed: Jun. 18, 2025

(30) Foreign Application Priority Data
Feb. 6, 2025 (KR) 10-2025-0015001

(51) Int. Cl. G11C 11/406

(52) U.S. Cl. CPC G11C 11/40615; G11C 11/40603; G11C 11/40618

(57) ABSTRACT

A memory system includes a memory device and a memory controller. The memory device includes at least one data storage area. The memory controller is coupled to the memory device and configured to transmit at least one command, scheduled to be transmitted within a preset clock range, to the memory device. The memory controller is configured to transmit an activation command included in the at least one command to the memory device when a command to be transmitted subsequent to the activation command is not a data input and output (input/output) command.

### CROSS-REFERENCE TO RELATED APPLICATIONS

This patent application claims the benefit of priority under 35 U.S.C. § 119(a) to Korean Patent Application No. 10-2025-0015001, filed on Feb. 6, 2025, the entire disclosure of which is incorporated herein by reference.

### TECHNICAL FIELD

Embodiments of the present disclosure described herein relate to a memory device, and more particularly, to a scheduling device and an operating method for a memory device using multi-clock instructions.

### BACKGROUND

Data processing systems including a memory system or a data storage device have been developed to store larger amounts of data, with faster rates of input and output (or write and read) of the data to/from the data storage device. The data storage device may include non-volatile memory cells and/or volatile memory cells for storing data.

The development of the data processing systems may include increasing computational capability and data processing speed in response to users'needs. The memory systems in the data processing systems may perform an operation of inputting and outputting data in response to a request input from an external device such as a host. The memory systems may receive data input/output requests from at least one external device, and may perform scheduling for plural tasks or operations corresponding to the data input/output requests to achieve efficient management or processing for the data input/output requests.

### BRIEF DESCRIPTION OF THE DRAWINGS

The description herein refers to the accompanying drawings wherein like reference numerals refer to like parts throughout the figures.

FIG. 1 illustrates a memory system according to an embodiment of the present disclosure.

FIG. 2 illustrates a memory device according to an embodiment of the present disclosure.

FIG. 3 illustrates an operation performed in a memory system according to an embodiment of the present disclosure.

FIG. 4 illustrates an example of a plurality of commands transmitted to a memory device in a memory system according to an embodiment of the present disclosure.

FIG. 5 illustrates a scheduling method according to an embodiment of the present disclosure.

FIG. 6 illustrates an effect of scheduling according to an embodiment of the present disclosure.

FIG. 7 illustrates a data processing apparatus according to an embodiment of the present disclosure.

FIG. 8 illustrates another data processing apparatus according to an embodiment of the present disclosure.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, a memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine’, ‘circuitry’ or ‘logic’ also covers an implementation of a processor or multiple processors or a portion of a processor and its (or their) accompanying software and/or firmware. The term ‘machine’, ‘circuitry’ or ‘logic’ also covers, for example, and if applicable to a particular claim element, an integrated circuit for a storage device.

As used herein, the terms ‘first’, ‘second’, ‘third’, and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect determination. The determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Embodiments of the present disclosure can provide a device and an operating method for improving data input and output (input/output) performance of a memory device by adjusting a command execution sequence regarding multi-clock commands or scheduling multi-clock commands in a memory device including a plurality of storage areas capable of independently performing data input/output operations.

In addition, an embodiment of the present disclosure can perform scheduling so that a data input/output command or a multi-clock command among a plurality of commands transmitted to a memory device including a plurality of storage areas capable of independently performing data input/output operations can be transmitted before other commands, thereby reducing the time spent on performing a plurality of data input/output commands.

Further, an embodiment of the present disclosure can prevent or avoid delay in performing a data input/output command by allowing a device or a memory controller performing scheduling to transmit other commands to be transmitted later than the data input/output command within a minimum (or sometimes required) period that should be secured between the data input/output commands so that the memory device can maintain an operational state for performing the data input/output command.

An embodiment of the present disclosure can provide a memory system including a memory device including at least one data storage area; and a memory controller coupled to the memory device and configured to transmit at least one command, scheduled to be transmitted within a preset clock range, to the memory device. The memory controller can be configured to transmit an activation command included in the at least one command to the memory device when a command to be transmitted subsequent to the activation command is not a data input and output (input/output) command.

The data input/output command can include at least one of a read command and a write command. The memory controller can be configured to transmit the data input/output command to the memory device prior to the activation command, when the command to be transmitted subsequent to the activation command is the data input/output command.

The activation command and the data input/output command can be multi-clock commands to be transmitted during plural clock cycles.

The preset clock range can include at least four clock cycles.

The at least one command can include a precharge command which is a single-clock command that is transmitted during a single clock cycle. The controller can be configured to transmit the precharge command to the memory device regardless of a transmission order of the data input/output command.

The memory controller can be configured to transmit the data input/output command to the memory device before the activation command when a command transmitted subsequent to the data input/output command is the activation command.

The at least one data storage area can include a plurality of memory banks. The activation command and the data input/output command can be transmitted to different banks among the plurality of memory banks.

The data input/output command can have a minimum burst period or a minimum column command delay period which is longer than the preset clock range.

The minimum column command delay period can include eight clock cycles.

In another embodiment, a method for operating a memory system can include determining at least one command scheduled to be transmitted within a preset clock range to a memory device comprising at least one data storage area; and transmitting, to the memory device, an activation command included in the at least one command when a command to be transmitted subsequent to the activation command is not a data input and output (input/output) command.

The method can further include transmitting the data input/output command included in the at least one command to the memory device prior to the activation command when the command to be transmitted subsequent to the activation command is the data input/output command.

The data input/output command can include at least one of a read command and a write command.

The activation command and the data input/output command can be multi-clock commands to be transmitted during plural clock cycles.

The preset clock range can include at least four clock cycles.

The at least one command can include a precharge command that is a single-clock command transmitted during a single clock cycle. The method can further include transmitting the precharge command to the memory device regardless of a transmission order of the data input/output command.

The at least one data storage area can include a plurality of memory banks. The activation command and the data input/output command can be transmitted to different banks among the plurality of memory banks.

The data input/output command can have a minimum burst period or a minimum column command delay period which is longer than the preset clock range.

The minimum column command delay period can include 8 clock cycles.

In another embodiment, a command scheduler is coupled to a memory device including at least one data storage area, and configured to determine a transmission timing of at least one command scheduled to be transmitted within a preset clock range. The command scheduler can be configured to transmit an activation command included in the at least one command to the memory device when a command transmitted following the activation command is not a data input and output (input/output) command.

The activation command and the data input/output command can be multi-clock commands transmitted during plural clock cycles. The data input/output command can include at least one of a read command and a write command.

These and other features and advantages of the invention will become apparent from the detailed description and the accompanying drawings of embodiments of the present disclosure.

Embodiments will now be described with reference to the accompanying drawings, wherein like numbers reference like elements.

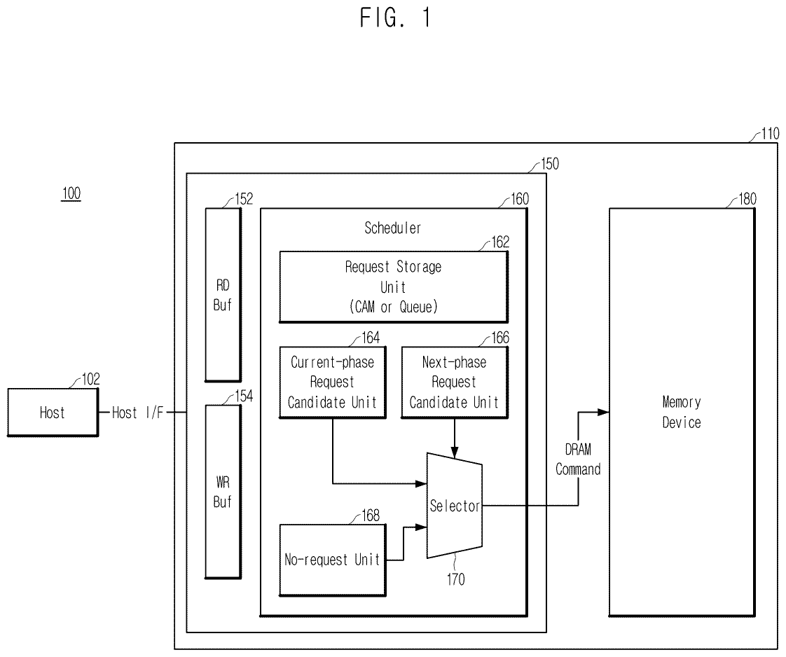

FIG. 1 illustrates a memory system 110 according to an embodiment of the present disclosure.

Referring to FIG. 1, a data processing system 100 can include a host 102 and the memory system 110. The memory system 110 can be coupled to the host 102 which is an external device. According to an embodiment, the data processing system 100 can further include an additional component for coupling the host 102 and the memory system 110.

The host 102 and the memory system 110 can perform data communication through at least one component, such as a data bus, a network, or a root hub. Data communication between the host 102 and the memory system 110 can be performed through a host interface (e.g., Host I/F). The host interface (e.g., Host I/F) between the host 102 and the memory system 110 can include mutually agreed upon standards for data transmission and reception. These standards may include various interface protocols for transmitting and receiving data, such as Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe), Serial-attached SCSI (SAS), Serial Advanced Technology Attachment (SATA), and Mobile Industry Processor Interface (MIPI). According to an embodiment, the host 102 and the memory system 110 may be connected via a Universal Serial Bus (USB). The Universal Serial Bus (USB) may include an expandable, hot-pluggable plug-and-play serial interface that ensures an economical standard connection to peripheral devices such as a keyboard, mouse, joystick, printer, scanner, storage device, modem, video conferencing camera, etc.

According to an embodiment, the memory system 110 can be implemented as one of various types of storage devices, such as a solid state drive (SSD), an MMC, an embedded MMC (eMMC), a reduced size MMC (RS-MMC), a multi media card (MMC) in the form of a micro-MMC, a secure digital (SD) card in the form of an SD, mini-SD, or micro-SD, a universal storage bus (USB) storage device, a universal flash storage (UFS) device, a compact flash (CF) card, a smart media (Smart Media) card, or a memory stick.

The memory system 110 can include a memory controller 150 and a memory device 180. The memory controller 150 can be configured to receive a command transmitted from the host 102, which is an external device, and transmit a response to the command to the host 102. For example, the command may be for checking an operating status of the memory system 110, storing data in the memory system 110, or reading data stored in the memory system 110. According to an embodiment, the host 102 can transmit various commands to the memory system 110 as needed. The memory system 110 can be configured to perform internal operations in response to the command of the host 102 and transmit a response to the host 102 based on an agreed upon standard or rule.

The memory controller 150 can include a read buffer (RD Buf) 152 and a write buffer (WR Buf) 154. The read buffer 152 is a component for processing a read command, and the write buffer 154 is a component for processing a write command. According to an embodiment, the memory controller 150 can process a read command and a write command through one buffer. However, in that instance, changes in the operation mode from a read mode to a write mode or from the write mode to the read mode can frequently occur. Frequent changes in the operation mode may lower the throughput of the memory system. To solve this concern, the memory system 110 can separate the read buffer 152 for processing a read command and the write buffer 154 for processing a write command, and process the read command and the write command through separate processing processes (e.g., separate pipelines).

The read buffer 152 and the write buffer 154 can have fixed sizes corresponding to internal resources and internal configurations. However, in accordance with an embodiment of the present disclosure, the sizes of the read buffer 152 and the write buffer 154 can be changed based on an operating environment or condition. In addition, the sizes of the read buffer 152 and the write buffer 154 can be different. Depending on the operating environment of the memory system, when there are many read commands to be processed, the memory system 110 can use more internal resources to process read commands than to process write commands. Conversely, when there are many write commands to be processed, the memory system 110 may use more internal resources to process write commands than to process read commands.

The memory controller 150 can include a command scheduler 160. The command scheduler 160 can include a request storage unit 162 configured to temporarily store a plurality of commands, including commands transmitted from the read buffer 152 and the write buffer 154 and commands for checking or controlling the operating state of the memory device 180. The request storage unit 162 can be understood as a space where multiple commands scheduled to be transmitted to the memory device 180 are temporarily stored. Depending on an embodiment, the request storage unit 162 can include a content addressable memory (CAM) or a queue.

For example, the content-addressable memory (CAM) may be a special memory which is configured to access data in storage space by addressing the actual data content. The CAM can be also called associative memory, and can be used in search applications that require high speed. The CAM can be more powerful and faster than general numeric address memory, and can be useful for information retrieval because it can search for the location of the desired information by using part of the stored content rather than the address to access the information stored in the memory.

A queue can have a first-in, first-out (FIFO) data structure. The queue is a type of list structure in which insertions are made at one end and deletions are made at the other end. For example, the queue can process one piece of data at a time, and data input and output can only be done at a fixed location. That is, adding (inserting, inputting) data to the queue can only be possible at the end (e.g., rear), and returning (deleting, outputting) data can only be possible at the beginning (e.g., front). The queue may have a linear data structure in which the relationship between the front and rear is 1:1. In an instance in which the request storage unit 162 is implemented as a queue, there is an advantage in that the complexity of processing commands can be reduced.

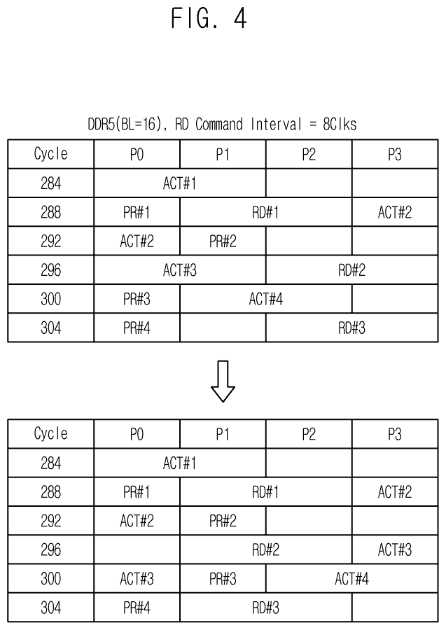

The command scheduler 160 can include a current-phase request candidate unit 164 and a next-phase request candidate unit 166. The current-phase request candidate unit 164 and the next-phase request candidate unit 166 can sequentially store commands that are scheduled to be transmitted to the memory device 180 within a preset clock range among a plurality of commands stored in the request storage unit 162. For example, if the preset clock range includes four clock cycles, the commands transmitted to the memory device 180 during the four clock cycles can be sequentially stored in the current-phase request candidate unit 164 and the next-phase request candidate unit 166. The commands stored in the current-phase request candidate unit 164 and the next-phase request candidate unit 166 will be described herein below with reference to FIG. 4.

The command scheduler 160 can include a no-request unit 168. The request storage unit 162 might not include a command transmitted to the memory device 180 within the preset clock range. That is, the current-phase request candidate unit 164 and the next-phase request candidate unit 166 may not include any commands. If there is no command transmitted to the memory device 180 within the preset clock range, the no-request unit 168 can be activated.

The command scheduler 160 can include a selector 170 (for example, a selection unit) that is configured to determine a command (e.g., a dynamic random access memory (DRAM) command) to be transmitted to the memory device 180 in response to input/instructions of the current-phase request candidate unit 164, the next-phase request candidate unit 166, and the no-request unit 168. In an instance in which the no-request unit 168 is activated, the selector 170 might not transmit any command to the memory device 180. In an instance in which the current-phase request candidate unit 164 includes a data input/output command (e.g., a read command or a write command), the selector 170 can transmit the corresponding data input/output command to the memory device 180. In an instance in which the current-phase request candidate unit 164 includes a data input/output command (e.g., a read command or a write command), the selector 170 can transmit the corresponding data input/output command to the memory device 180. If the current-phase request candidate unit 164 includes a command other than the data input/output command (e.g., a read command or a write command), the selector 170 can check the command included in the next-phase request candidate unit 166 before transmitting the command to the memory device 180.

In response to the command included in the next-phase request candidate unit 166, the selector 170 can output one of the commands included in the current-phase request candidate unit 164 or the next-phase request candidate unit 166 to the memory device 180. For example, if the current-phase request candidate unit 164 includes an activation command and the next-phase request candidate unit 166 includes a data input/output command (e.g., a read command or a write command), the selector 170 can output the data input/output command (e.g., a read command or a write command) included in the next-phase request candidate unit 166 to the memory device 180 rather than the activation command included in the current-phase request candidate unit 164. Conversely, if the current-phase request candidate unit 164 includes a data input/output command (e.g., a read command or a write command) and the next-phase request candidate unit 166 includes an activation command, the selector 170 can transmit the data input/output command to the memory device 180 and then transmit the activation command to the memory device 180.

According to an embodiment, the activation command and the data input/output command (e.g., a read command or a write command) can be multi-clock commands. A multi-clock command includes a command that the memory controller 150 is promised (i.e., reserved, retained, booked, directed) to transmit to the memory device 180 during plural (or multiple) clock cycles. There may be various types of commands that the memory controller 150 may be configured to transmit to the memory device 180, some of which may be multi-clock commands and others may be single-clock commands. A single-clock command includes a command that the memory controller 150 is promised (directed) to transmit to the memory device 180 during a single clock cycle. For example, a precharge command may be a single-clock command. Meanwhile, in the case of a data input/output command (e.g., a read command or a write command), a minimum interval or period between commands may be required in accordance with a burst length (BL). The minimum interval between data input/output commands can be set to a minimum burst period or a minimum column command delay period (e.g., Column to Column Delay, tCCD).

According to an embodiment, the burst length (BL) may be increased to improve the data input/output performance of the memory system 110. For example, the burst length (BL) of DDR5 may be doubled from 8 to 16 compared to DDR4. In this instance, the minimum interval or period between commands can be doubled in terms of the number of clock cycles. For example, when considering data transmission of DDR that uses both the rising/falling edges of the clock, the time required to transmit data with a burst length of 8 (BL=8) is 4 clock cycles, and the time required to transmit data with a burst length of 16 (BL=16) is 8 clock cycles. Therefore, the minimum interval or period between commands can be increased from 4 clock cycles to 8 clock cycles to avoid overlap in units of burst length (BL) while sequentially issuing read or write commands. However, if the speed of the reference clock for the operation of the memory system is doubled, the minimum interval between commands might not increase substantially or physically.

Multi-clock commands may be thought of as being slower than single-clock commands (for example, based on the separate multiple commands), but there may be no difference in actual or physical time. In addition, even in instances in which the number of clock cycles increases for command or data transmission, the number of pins or pads for transmitting commands and addresses may be reduced. For example, a command or address (command/address) transmitted in a single clock cycle (i.e., 1 cycle) in DDR4 may be transmitted in multiple clock cycles (e.g., 2 cycles) in DDR5. On the other hand, DDR4 has 26 pins or pads for transmitting commands or addresses, but DDR5 has 14 pins or pads for transmitting commands or addresses. If the number of pins or pads is reduced, the package size or number of balls of the memory device 180 could be reduced, thereby lowering a production cost and facilitating a design of a substrate or a board (e.g., printed circuit board (PCB)) included in the memory system 110.

In addition, in DDR4, Data Bus Inversion (DBI) may be applied to pins or pads for transmitting data. Bus inversion (BI) is an input/output (I/O) signaling technique that aims to reduce direct current (DC) power consumption by selectively inverting the data bus for systems where power consumption between alternate signaling states is asymmetrical. Meanwhile, DDR5 can apply bus inversion to pins or pads for transmitting commands or addresses rather than pins or pads for transmitting data.

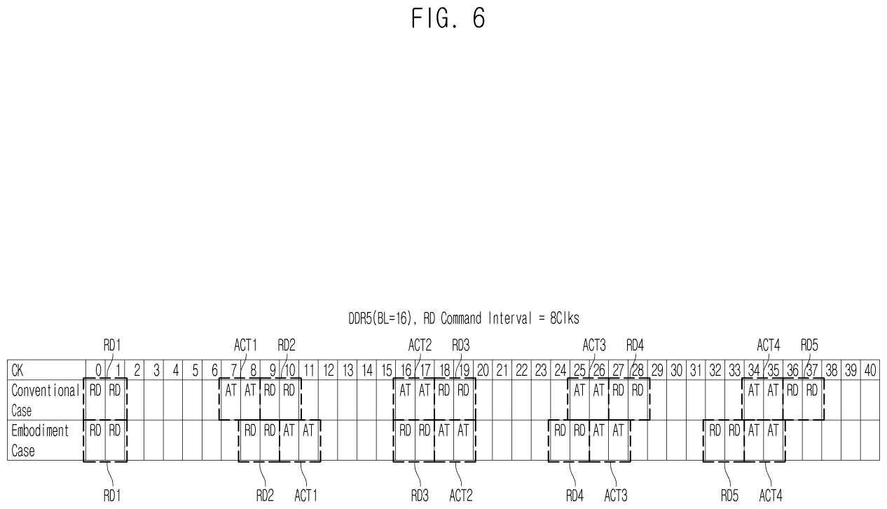

As described above, the command scheduler 160 in the memory system 110 can change a transmission order of multi-clock commands to increase the number of commands and data, transmitted and received between the memory controller 150 and the memory device 180, within a preset time period. The effect of the command scheduler 160 is described herein below with reference to FIG. 6.

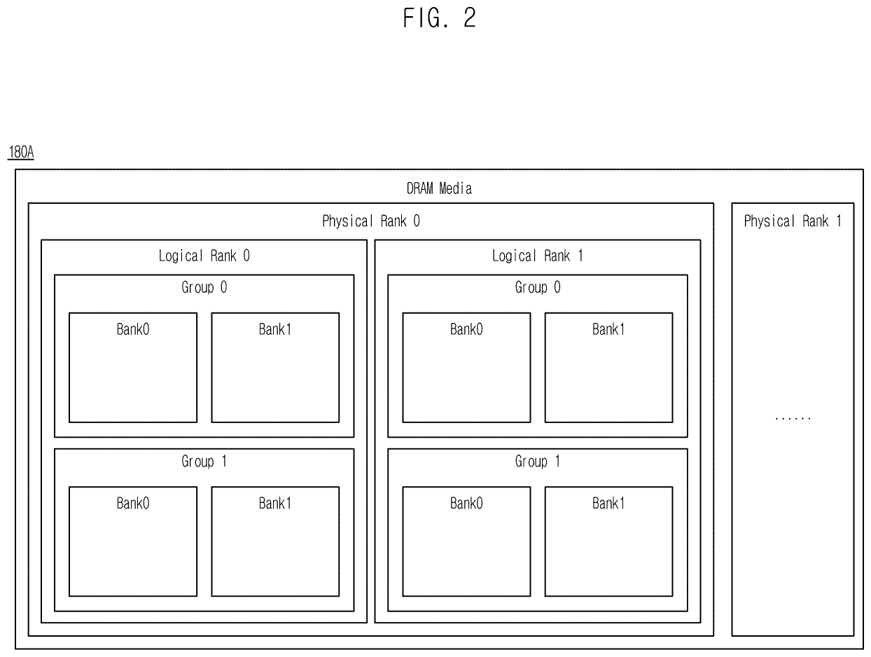

FIG. 2 illustrates a memory device 180A according to an embodiment of the present disclosure.

Referring to FIG. 2, the memory device 180A can include a plurality of data storage areas. The memory device 180A is shown as one example of the memory device 180 described in FIG. 1. The memory device 180A can be configured in various forms.

The memory device 180A can include a plurality of banks (illustrated, in a non-limiting example by way of convenience of description, as Bank0, Bank1). Here, a bank is a logically separated area, and data in the bank can be accessed at once, and each bank can operate independently. A word line can have a row address, and a bit line to which a sense amplifier is connected can have a column address. The banks can perform a read operation or a write operation independently and simultaneously. However, because circuits and paths from pins or pads of the package of the memory device 180A to each bank are shared with other banks, a time interval or period, e.g., the minimum column command delay period (Column to Column Delay, tCCD), should be secured between read commands or write commands transmitted to other banks. Each bank Bank0, Bank1 can include multiple pages. A page may indicate the number of memory cells (i.e., the number of bits) connected to a word line. For example, the size of a page can be 1 KB, 2 KB, or 4 KB. The page size can be the same as the number of sense amplifiers that would be turned on at one time. A smaller page size can be advantageous in reducing power consumption because only a smaller number of sense amplifiers need to be operated.

As the number of banks in the memory device 180A increases, a bank group, which is a unit that groups multiple banks, can be set to efficiently implement, manage, and control a large number of banks. Referring to FIG. 2, a bank group (e.g., Group 0, Group 1) can include a group of banks (for example, two or four banks). When a bank group is set, portions that share circuits and paths between banks belonging to different bank groups could be reduced, so that the minimum interval or period between commands, etc. could be reduced more than between banks within the same bank group. For example, the time interval or period between commands between banks belonging to different bank groups can be defined as the first minimum column command delay period (e.g., Short Column to Column Delay, tCCD_S), and the time interval or period between commands between banks belonging to the same bank group can be defined as the second minimum column command delay period (e.g., Long Column to Column Delay, tCCD_L). The first minimum column command delay period (e.g., tCCD_S) is shorter than the second minimum column command delay period (e.g., tCCD_L). Therefore, the memory controller 150 can transmit a read command or a write command to the memory device 180A at a shorter interval or period as the bank groups are divided into multiple groups.

In addition, the memory device 180A could be divided into ranks indicating physical groups of memory chips. Each rank can be accessed in parallel. Each rank can have an independent structure. However, each rank can share a channel for exchanging data with the memory controller 150. Referring to FIG. 2, the memory device 180A can be divided into a plurality of physical ranks (e.g., Physical Rank 0, Physical Rank 1), and each physical rank (e.g., Physical Rank 0, Physical Rank 1) can include a plurality of logical ranks (e.g., Logical Rank 0, Logical Rank 1). Each logical rank (e.g., Logical Rank 0, Logical Rank 1) can include a plurality of bank groups (e.g., Group 0, Group 1).

According to an embodiment, the memory device 180A may be designed hierarchically, and the data input/output performance of the memory system 110 may be improved through a device and an operating method for distributing and storing a large amount of data in units of hierarchies by setting the minimum time between commands corresponding to each layer differently, or for reducing or preventing power consumption or data errors.

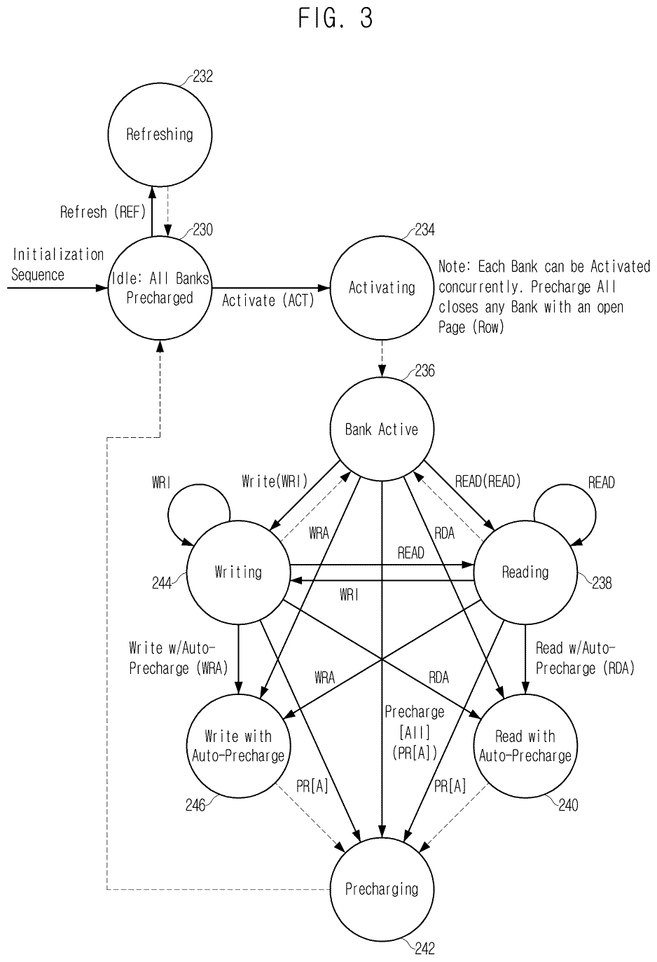

FIG. 3 describes an operation performed within a memory system according to an embodiment of the present disclosure. Specifically, FIG. 3 describes an operation mode of the memory device 180 described in FIG. 1 and the change in the operation mode of the memory device 180 in response to the command transmitted to the memory device 180 by the memory controller 150. The operation mode of the memory device 180 described in FIG. 3 and the change in the operation mode of the memory device 180 can vary depending on an embodiment.

Referring to FIG. 3, the memory controller 150 can perform an initialization sequence for the memory device 180. The initialization sequence can include operations such as supplying power and adjusting settings to enable data communication between the memory controller 150 and the memory device 180. After the initialization sequence, all banks in the memory device 180 can be precharged in an idle state 230.

When the memory controller 150 sends a refresh command REF for a bank being in the idle state 230, the bank can be in a refresh state (for example, refreshing, implementing a refresh operation) 232. The bank can be automatically switched to the idle state 230 after the refresh operation is completed. Herein, the switching of the operating state by the command can be indicated by a solid arrow, and the switching of the state automatically without a command can be indicated by a dotted arrow.

When the memory controller 150 transmits a command to activate (for example, an activation command) ACT to a specific bank in the memory device 180, the bank can be switched from the idle state 230 to the activation operation state (e.g., activating) 234 and then to an activation state (e.g., bank active) 236. The activation operation state 234 can vary depending on an embodiment. For example, each bank can be activated simultaneously (for example, concurrently), or only some of the plurality of banks can be activated. The activation operation can include an operation of precharging an open page corresponding to a row address in the bank being activated. The instruction Precharge[All] can close any bank with an open page (for example, a row).

The memory device 180 should (for example, is configured to) first open the bank before the bank is ready to respond to a read command or a write command (e.g., activation operation). The memory controller 150 can send the activation command ACT to specify a rank, a bank, and a page (e.g., a row) to be accessed, so that the memory device 180 performs the activation operation. The time taken to activate the bank is called a row-column (or command) delay and is denoted by tRCD. This variable can indicate the minimum time required to latch a command in a command interface, program a control logic, and read data from a memory array to the sense amplifier in preparation for a column-level access.

When a specific bank is in the activation state 236 and a precharge command (e.g., Precharge[All], PR[A]) is delivered to the bank, the bank can be switched to the precharge state (precharging) 242.

When a specific bank is in the activation state 236, the operational state can vary depending on a data input/output command. For example, when a write command WRI is transmitted for the corresponding bank, the corresponding bank may be switched from the activation state 236 to a write state (writing) 244. When the write command (Write(WRI)) is transmitted in the write state 244, the corresponding bank can maintain the write state 244. When the write operation is completed, the corresponding bank can be automatically switched from the write state 244 to the activation state 236.

When a specific bank is in the write state 244 and a write and automatic precharge command WRA is transmitted for the corresponding bank, the corresponding bank can be switched from the write state 244 to a write and automatic precharge state (for example, write with auto-precharge) 246. When the precharge operation is terminated in the write and automatic precharge state 246, the corresponding bank can be automatically switched to the precharge state 242. In addition, if a precharge command PR[A] is transmitted to a specific bank when the specific bank is in the write state 244, the bank can be switched to the precharge state 242. Afterwards, the bank can be automatically switched from the precharge state 242 to the idle state 230.

Similar to the switching of the operation state for the write command, when a specific bank is in the active state 236, a read command READ for the bank can be transmitted. When the read command READ for the bank is transmitted, the bank is switched from the active state 236 to a read state (e.g., reading) 238. When the read command READ is transmitted in the read state 238, the bank can maintain the read state 238. When the read operation is completed, the bank may be automatically switched from the read state 238 to the activation state 236.

When a specific bank is in the read state 238 and a read and automatic precharge command (for example, read w/auto precharge) RDA is transmitted to the bank, the bank can be switched from the read state 238 to a read and automatic precharge state 240. When the precharge operation is terminated in the read and automatic precharge state 240, the bank can be automatically switched to the precharge state 242. In addition, when a specific bank is in the read state 238 and the precharge command PR[A] is transmitted, the bank can be switched to the precharge state 242. Thereafter, the bank can be automatically switched from the precharge state 242 to the idle state 230.

When a specific bank is in the read state 238, a write command WRI can be input. In this instance, the bank can be switched from the read state 238 to the write state 244. Conversely, when a specific bank is in the write state 244, the read command READ can be input. In this case, the bank can be switched from the write state 244 to the read state 238. In addition, when a write and automatic precharge command WRA or a read and automatic precharge command RDA is transmitted to a specific bank, the bank can be switched from the write state 244 or the read state 238 to the write and automatic precharge state 246 or the read and automatic precharge state 240.

As described above, after the activation operation of the bank, the open bank can perform an operation in response to at least one read command READ and at least one write command WRI. This operation can specify a start column address to be accessed, as well as set the time taken to read a data byte from an open page as a column address strobe (CAS) latency (e.g., CL or tCAS). This variable can indicate a minimum time required to latch a command in the command interface, program a control logic, prefetch a requested data from the sense amps to the input/output (I/O) buffers, and place a first data of the requested data on the memory bus.

According to an embodiment, the memory controller 150 can open one page per bank at a time. The memory controller 150 should close (or may be configured to close) an open page before accessing another page in a same bank. If the page is open (or remains open, is opened), the memory controller 150 can issue a combination of the read commands READ and the write commands WRI, and in some instances switch back and forth between the two commands (e.g., READ, WRI). This can be done until the open page is no longer needed or a pending request to read and write data from another page in the same bank requires the current page to be closed to allow access to the other page. This can be accomplished by the memory controller 150 issuing the precharge command PR to close only the designated bank or the precharge command (e.g., Precharge [All], (PR[A])) to close all open banks of the rank.

As described above, the memory controller 150 can transmit the write and auto precharge command WRA or the read and auto precharge command RDA instead of the last read command among multiple read commands or the last write command among multiple write commands as the precharge command. In this instance, the last read or write operation for the corresponding bank can be effectively combined with the precharge operation. This can allow the control logic within the memory device 180 to automatically close open pages as soon as a specific condition is met. The specific condition can be that the minimum RAS (Row Access Strobe) activation time (tRAS) has elapsed since the activation command ACT was issued, and the minimum read-to-precharge delay (tRTP) has elapsed since the most recent read command REA) was issued.

The precharge operation can prepare the data lines and sense circuitry to transfer the charge stored in the sense amplifier back to the open page of the individual memory cell to reverse a previous destructive read and prepare the memory device 180 to sample the next memory page to be accessed. The time to precharge the open bank can be set as the RAS precharge delay (tRP). The minimum time interval or period between consecutive activation commands ACTs for the same bank can be determined by the row cycle time (tRC) of the memory device 180. According to an embodiment, the row cycle time (tRC) can be determined by simply adding the RAS activation time (tRAS) and the RAS precharge delay (tRP). The minimum time interval or period between activation commands ACTs for different banks can be set as the read-to-read delay (tRRD).

FIG. 4 illustrates an example of plural commands transmitted to a memory device in a memory system according to an embodiment of the present disclosure. FIG. 4 illustrates an example of a case where a minimum time interval or period (e.g., RD Command Interval) of a read command is 8 clock cycles (i.e., 8 Clks) in DDR5 with a burst length (BL) of 16 (i.e., BL=16).

Referring to FIG. 4, the memory controller 150 can transmit a first activation command ACT#1 (for example, at cycle 284) to the memory device 180 during multi-clock cycles of an arbitrary point in time (e.g., a 285th clock cycle, P0) and a 286th clock cycle (e.g., P1). The first activation command ACT#1 is a multi-clock command. During the following two clock cycles (e.g., P2 to P3, i.e., 287th to 288th clock cycles), the memory controller 150 might not transmit any command to the memory device 180.

Thereafter, the memory controller 150 can transmit a first precharge command PR#1 to the memory device 180 at a 289th clock cycle. Here, the precharge command is a single-clock command.

Thereafter, the memory controller 150 can transmit the first read command RD#1 to the memory device 180 during 290th to 291st clock cycles (e.g., P1, P2). The first read command RD#1, which is a data input/output command, is a multi-clock command.

Thereafter, the memory controller 150 can transmit a second activation command ACT#2 to the memory device 180 during two clock cycles of 292nd to 293rd clock cycles (e.g., P3, P0). Thereafter, the memory controller 150 can transmit a second precharge command PR#2 to the memory device 180 at a 294th clock cycle.

As described above, there is a minimum interval or period between the activation command and the data input/output command (e.g., a read command or a write command). The memory controller 150 can transmit multiple activation commands and data input/output commands to the memory device 180 in compliance with the minimum interval or period.

Referring to FIG. 4, the second read command RD#2 can be transmitted to the memory device 180 at the 298th clock cycle (P1) that is a minimum interval (e.g., RD Command Interval, 8 Clks) after the time point at which the first read command RD#1 is transmitted (i.e., the 290th clock cycle, P1). However, due to the third activation command ACT#3, the second read command RD#2 is transmitted to the memory device 180 at the 299th clock cycle (P2), not the 298th clock cycle (P1). That is, in the example described in FIG. 4, the data input/output performance of the memory system 110 could be improved when multiple read commands RD#1, RD#2, RD#3 are transmitted to the memory device 180 at minimum intervals of 8 Clks. However, when the memory controller 150 fails to adjust an order or sequence of multiple commands transmitted to the memory device 180, the memory controller 150 might transmit the data input/output commands to the memory device 180 after a longer time than the minimum interval or period.

As described in FIG. 1 and FIG. 4, in instances in which the command scheduler 160 in the memory controller 150 can compare or check commands to be transmitted to the memory device 180 within a preset time range, in order to improve the data input/output performance, the command scheduler 160 could transmit the second read command RD#2 to the memory device 180 during the 298th to 299th clock cycles (P1, P2), and sequentially transmit the third activation command ACT#3, the fourth precharge command PR#3, and the fourth activation command ACT#4 during 300th to 304th clock cycles (P3, P0, P1, P2, P3).

In addition, when the transmission time of the second read command RD#2 becomes faster by a single clock cycle, the transmission time of the third read command RD#3 can become faster by one clock cycle. Through this procedure, the data input/output operation of the memory system 110 could be improved.

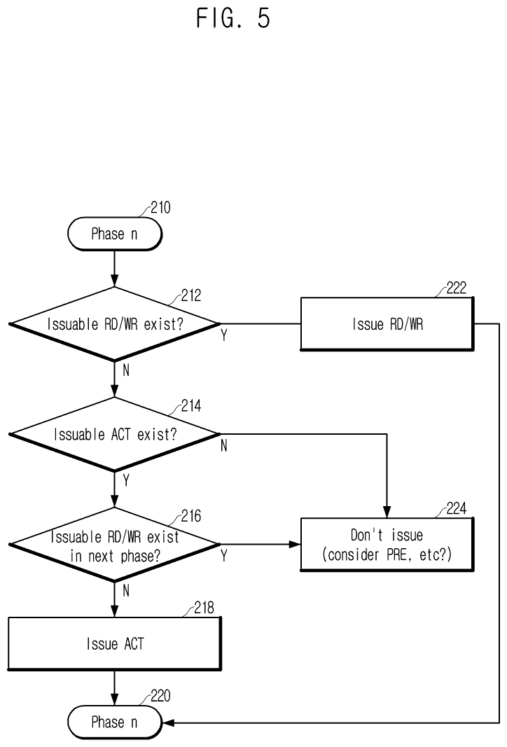

FIG. 5 describes a scheduling method according to an embodiment of the present disclosure. FIG. 5 is an example describing an operation method of the command scheduler 160 described in FIGS. 1 to 4. According to an embodiment, the operation method of the command scheduler 160 in the memory system 110 can vary.

Referring to FIG. 5, the memory system 110 can perform scheduling for multiple commands at a specific operation point (Phase n) (operation 210).

First, the memory system 110 may check whether there is a data input/output command (e.g., a read command or a write command, RD/WR) to be issued at the corresponding operation point, e.g., which the memory controller 150 will transmit to the memory device 180 (i.e., does an issuable RD/WR exist?) (operation 212).

When there is a data input/output command at the corresponding operation point (Yes (Y) in the operation 212), the memory controller 150 can transmit the corresponding data input/output command (e.g., issue RD/WR) to the memory device 180 (operation 222). Thereafter, command scheduling at the corresponding operation point can be terminated (at phase n) (operation 220).

When there is no data input/output command at the corresponding operation time (No (N) in the operation 212), the memory controller 150 can check whether there is an activation command ACT to be transmitted to the memory device 180 at the corresponding operation time (i.e., does an issuable ACT exist?) (operation 214).

When there is an activation command at the corresponding operation time (Yes (Y) in the operation 214), the memory controller 150 can check whether there is the data input/output command (e.g., RD/WR) to be transmitted to the memory device 180 at the next operation time following the corresponding operation time (i.e., does an issuable RD/WR exist in the next phase?) (operation 216).

When there is no data input/output command (e.g., RD/WR) to be transmitted to the memory device 180 at a next operation time (No (N) in the operation 216), the memory controller 150 can transmit the activation command ACT at the corresponding operation time to the memory device 180 (operation 218). Thereafter, the command scheduling at the corresponding operation time can be terminated (operation 220).

When there is no activation command at the corresponding operation time (No (N) in the operation 214) or there is a data input/output command (e.g., RD/WR) to be transmitted to the memory device 180 at the next operation time (Yes (Y) in the operation 216), the memory controller 150 might not transmit the activation command at the corresponding operation time to the memory device 180 (but, could transmit the precharge command (e.g., PRE), etc.) (operation 224).

When the activation command at the corresponding operation time is not transmitted to the memory device 180 (operation 224), the memory controller 150 can change an order of commands to be transmitted to the memory device 180 in response to the type of command, the minimum interval or period between commands, etc., as described in FIG. 1 and FIG. 4. For example, as described in FIG. 4, the memory controller 150 can postpone the order of commands other than data input/output commands so that the data input/output commands could be transmitted to the memory device 180 at an earlier time.

FIG. 6 illustrates the effect of scheduling according to an embodiment of the present disclosure. FIG. 6 illustrates, as an example, the data input/output performance of the memory system 110 that varies depending on the operating method of the memory system 110 described in FIGS. 1 to 5. Similar to FIG. 4, FIG. 6 illustrates, as an example, the case where the minimum time interval or period (RD Command Interval) of a read command is 8 clock cycles (i.e., 8 Clks) in DDR5 with a burst length (BL) of 16.

First, in the case of a conventional memory system (i.e., conventional case) that does not perform scheduling for plural commands, the first read command RD1 can be transmitted to the memory device 180 at first and second clock points (e.g., CK0-CK1). Thereafter, the first activation command ACT1 can be transmitted to the memory device 180 at eighth and ninth clock points (e.g., CK7-CK8) (where the activation command is denoted as AT in the intervals of FIG. 6), and the second read command RD2 can be transmitted to the memory device 180 at tenth and eleventh clock points (e.g., CK9-CK10). A plurality of activation commands ACT1, ACT2, ACT3, ACT4 and a plurality of read commands RD1, RD2, RD3, RD4, RD5 can be sequentially transmitted to the memory device 180. The time at which the fifth read command RD5 is transmitted to the memory device can be 37th to 38th clock points (e.g., CK36-CK37).

In contrast, in accordance with an embodiment of the present disclosure (i.e., embodiment case), when a data input/output command is scheduled to be transmitted following the activation command, the memory controller 150 can transmit the data input/output command to the memory device 180 before the activation command. The memory controller 150 can transmit the first read command RD1 to the memory device 180 at the first to second clock points (e.g., CK0-CK1). Thereafter, the memory controller 150 can transmit the second read command RD2 to the memory device 180 at ninth to tenth clock points (e.g., CK8CK9) corresponding to the minimum interval or period of the read command, instead of transmitting the first activation command ACT1 to the memory device 180 at eighth to ninth clock points (e.g., CK7-CK8). After transmitting the second read command RD2 to the memory device 180, the memory controller 150 can transmit the first activation command ACT1 scheduled to be transmitted to the memory device 180 at the eighth to ninth clock points (e.g., CK7-CK8) to the memory device 180 at eleventh to twelfth clock points (e.g., CK10-CK11). The memory controller 150 can change the order in which the plurality of activation commands ACT1, ACT2, ACT3, ACT4 and the plurality of read commands RD2, RD3, RD4, RD5 are transmitted to the memory device 180. Through this procedure, the time point at which the memory controller 150 transmits the fifth read command RD5 to the memory device 180 can be the 33rd to 34th clock points (e.g., CK32-CK33).

Compared to a conventional memory system, the memory system 110 according to an embodiment of the present disclosure can advance the time point at which the fifth read command RD5 is transmitted from 37th to 38th clock points (e.g., CK36-CK37) to 33rd to 34th clock points (e.g., CK32-CK33) (i.e., 4 clock cycle difference). This difference can become larger in the procedure in which the memory system 110 processes the plurality of data input/output commands. In addition, various simulations may be implemented to check (or confirm) that the memory system 110 can bring about a difference in command transmission timing of at least 2%. This improvement can bring about a greater effect as the computational amount of the memory system 110 increases.

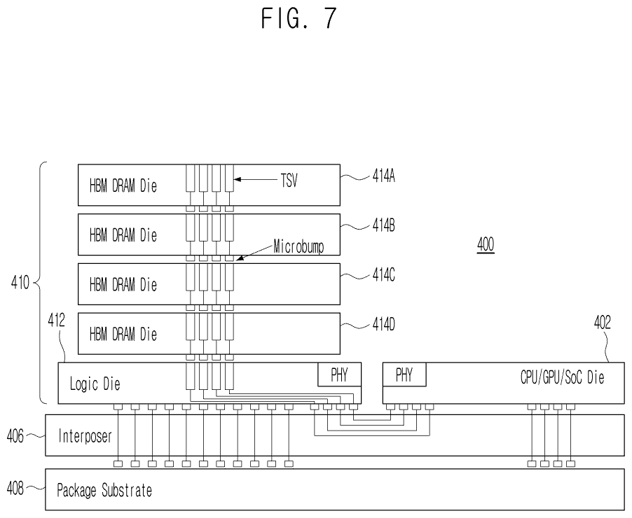

FIG. 7 illustrates a data processing apparatus 400 according to an embodiment of the present disclosure.

Referring to FIG. 7, the data processing apparatus 400 can be implemented in the form of a multi-chip package including a plurality of semiconductor devices or a plurality of semiconductor chips. According to an embodiment, the data processing apparatus 400 can include a high bandwidth memory (HBM) module 410. The HBM module 410 can correspond to the memory system 110 described in FIG. 1.

The data processing apparatus 400 can include an interposer 406 disposed on a package substrate 408. The interposer 406 can provide a path for data communication between a plurality of devices or a plurality of components. The interposer 406 can be used to simplify the manufacturing process of a multi-chip package for supporting high-speed data communication and to improve signal quality in high-speed data communication. The HBM module 410 disposed on the interposer 406 can include a plurality of memory dies 414A to 414D and a logic die 412. The HBM module 410 described in FIG. 7 may include four memory dies 414A to 414D, but the number of memory dies can be 8, 12, 16, or etc., depending on required performance included in the HBM module 410. According to an embodiment, each of the memory dies 414A to 414D can include a data storage area including volatile memory cells (e.g., DRAM, static random-access memory (SRAM), etc.). According to an embodiment, the plurality of memory dies 414A to 414D can include a data storage area including memory cells of different types (e.g., volatile memory cells and non-volatile memory cells). For example, some of the plurality of memory dies 414A to 414D can be a DRAM memory die, and others may be a NAND memory die.

The plurality of memory dies 414A to 414D can be vertically stacked and can correspond to a plurality of memory devices (e.g., 180 described in FIG. 1). The plurality of memory dies 414A to 414D can transmit and receive data or signals through Through-Silicon Vias (TSVs) for vertical electrical connection between the memory dies. In addition, each of the plurality of memory dies 414A to 414D can include a micro bump to maintain a gap with the adjacent die and ensure electrical contact.

A host 402 connected to the HBM module 410 and configured to process data can be placed (disposed or connected) on the interposer 406. The host 402 can include a central processing unit (CPU), a graphics processing unit (GPU), or a System-on-a-Chip (SoC). The host 402 can correspond to the external device (i.e., the host 102) connected to the memory system 100 described in FIG. 1. According to an embodiment, the HBM module 410 can be directly connected to the host 402, such as a CPU or a GPU, and can increase bandwidth to bypass the memory controller. This structure might reduce data transmission delay time and improve system performance. For example, the host 402, such as a CPU or a GPU, can send a data read/write request to the HBM module 410, and the HBM controller included in the logic die 412 can analyze a request input from the host 402 and transmit the request to a specific memory bank included in the plurality of memory dies 414A to 414D. The specific memory bank included in the plurality of memory dies 414A to 414D can read or write data requested through the TSV and transmit read data to the host 402, such as a CPU or a GPU, through the interposer 406. In addition, the host 402, such as a CPU or GPU, can process data output from the HBM module 410 and return a result (e.g., data) to the HBM module 410.

According to the embodiment, the HBM controller included in the logic die 412 can include the controller 150 and the buffers 152, 154 described in FIG. 1. The HBM controller included in the logic die 412 can efficiently control the memory banks included in the plurality of memory dies 414A to 414D and manage data transfer based on the priorities assigned to the plurality of data input/output requests.

Further, the logic die 412 and the host 402 can include at least one component corresponding to a physical layer PHY which is responsible for transmitting and receiving data or signals therebetween.

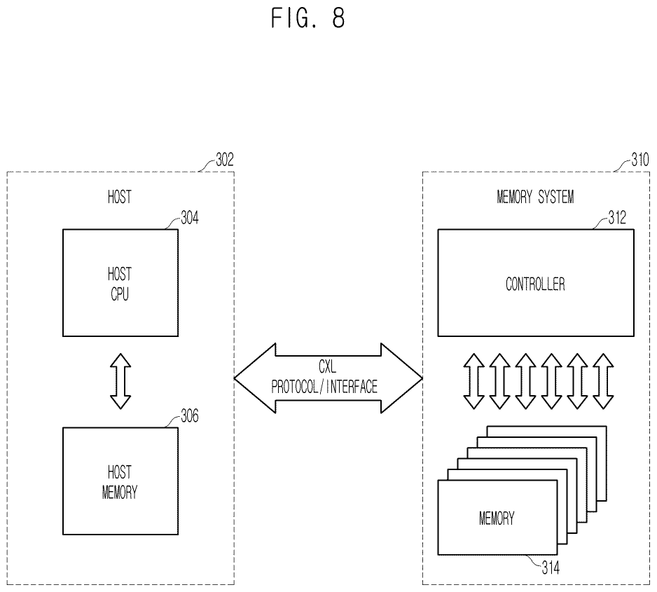

FIG. 8 illustrates another data processing apparatus according to an embodiment of the present disclosure.

Referring to FIG. 8, the data processing apparatus may include a host 302 and a memory system (e.g., compute express link (CXLTM) device) 310. The host 302 and the memory system 310 can perform data communication via a computer-memory link-based (e.g., CXLTM) protocol or interface. A controller 312 within the memory system 310 can include the controller 150 and the buffers 152, 154 described in FIG. 1. The controller 312 can manage and control data I/O operations performed in a memory device (or a CXLTM memory device) 314 based on priorities assigned to plural data I/O requests.

The memory system 310 can be designed to support memory-centric computing technology. The memory-centric computing technology can provide a dynamically scalable shared memory that overcomes the limitations of large-capacity data processing performance and capacity occurring in one type of CPU-centric systems that have been proposed, in line with demands or requirements for a memory disaggregation system. Thus, the system scale can be flexibly maintained in line with requirements regarding the data processing apparatus. Due to the explosive increase in amounts of data from emerging applications such as big data and artificial intelligence (AI), the data processing apparatus including at least one computing device can be designed or built to satisfy large-capacity, high-bandwidth memory, or innovative architectural changes. The number of servers and memory devices may be continually increased to meet corresponding increasing memory requirements. The computer-memory link-based protocol or computer-memory link-based interface can be provided to support large-capacity and high-bandwidth memory.

Memory disaggregation can be an architectural solution that separates a memory (e.g., a memory device) from a compute node (e.g., a computing device), allowing a system designer to flexibly expand additional memory capacity independently of each computing server while meeting the memory requirements of user applications. For example, a computing server with high memory usage can use a memory device located farther away from other nodes included in a disaggregated group. Accordingly, this disaggregation scheme can manage or use resources more efficiently than one type of dedicated CPU and memory architectures that have been proposed.

The computer-memory link (e.g., Compute Express Link, CXL®) can be provided to accelerate architectural transition to memory disaggregation. The computer-memory link is an industry-supported cache-coherent interconnect (CCI) for various processors to efficiently expand memory capacity through a memory semantic protocol. Unlike a host memory 306 that is entirely dependent on a host central processing unit (e.g., CPU) 304, a memory device 314 connected via the CXL-based protocol or CXL-based interface to the host 302 can include additional data or values such as data processing engines through handshaking communication, as a memory.

The host 302 can include the host CPU 304 and the host memory 306. The numbers and configurations of the host CPU 304 and the host memory 306 can vary depending on the performance, operating requirements, operating speed, and data I/O speed of the host 302. The host CPU 304 and the host memory 306 can transmit and receive data through a communication interface protocol mutually agreed upon with each other. This may be implemented using various communication standards or interfaces such as described herein above with respect to FIG. 1. According to an embodiment, the host 302 and the host memory 306 may be coupled via a Universal Serial Bus (USB) that includes an expandable, hot-pluggable plug-and-play serial interface that provides a connection to peripheral devices such as a keyboard, mouse, joystick, printer, scanner, storage device, modem, video conferencing camera, etc.

In FIG. 8, the host 302 can perform data communication with the memory system 310 through the computer-memory link-based protocol or interface (e.g., CXL™ protocol or CXL™ interface). CXL™ (Compute Express Link) and PCIe (Peripheral Component Interconnect Express) are both standard interfaces for connecting peripherals and CPUs in a computer system. However, there are differences in several aspects between the CXL™ and the PCIe. First, the PCIe is designed as a standard for general input/output devices, while the CXL™ is an interface specialized for memory access and high-speed data transmission in a high-performance computing environment. Thus, the CXL™ is designed so that the CPU can directly access the memory of the device, while the PCIe may have limited such functions. In addition, while the PCIe uses a unidirectional communication way, the CXL™ can support bidirectional communication. For example, the CXL™ devices can support sending and receiving data simultaneously. Because the CXL™ is designed to maintain backward compatibility with the PCIe, the CXL™ device may be designed or implemented by utilizing one type of PCIe infrastructure that has been proposed.

According to an embodiment, data communication of the memory device 314 (e.g., a CXL™ memory device) distributed to the host central processing unit (e.g. CPU) 304 may have a limited interface bandwidth, as compared to that of the host memory 306. For example, in cases of DDR4 DIMM and DDR5 DIMM used as the host memory 306, the DIMM has 64-bit (i.e., 8-byte) data width. The maximum bandwidth could be 25.6 GB/s (=3.2 Gbps×8 bytes) for DDR4 and 38.4 GB/s (=4.8 Gbps×8 bytes) or 51.2 GB/s (=6.4 Gbps×8 bytes) for DDR5. Accordingly, the interface bandwidth may be 0.4^{s-1} (=25.6 GB/s/64 GB) and 0.6^{s-1} (=38.4 GB/s/64 GB) or 0.8^{s-1} (=51.2 GB/s/64 GB) when a storage capacity of each chip is 64 Gb. On the other hand, the interface bandwidth of the memory system 310 may be very limited to 0.0625^{s-1} (=32 GB/s(@PCIe5.0×8)/512 GB). This bandwidth difference can limit the input/output performance of the data processing apparatus.

To overcome above-described issues, the memory system 310 may include a controller 312 (e.g., a CXL™ core) designed and used for near data processing (NDP) (or near-distance data processing). The near data processing (NDP) can be a computing scheme for improving or enhancing the efficiency of data processing. The near data processing (NDP) may be based on a configuration in which the controller 312 (e.g., at least one processor or core that processes data) is arranged or located close to a data storage or memory such as the memory device 314.

In one type of computing model that has been proposed, the host CPU 304 would retrieve data from the memory device 314 coupled to expand the host memory 306, process the data, and store results back in the memory device 314. However, in applications that require processing a large amount of data, that scheme may cause a bandwidth bottleneck between the memory device 314 and the host CPU 304. To solve this issue, the near data processing (NDP) may be designed to place the controller 312 (e.g., a processor that processes data) close to the memory device 314 in which the processed data is stored. That is, instead of moving data from the memory device 314 to the host CPU 304, the controller 312, which is the processor that performs data processing, can be included in the memory system 310 which is the location of the data. This configuration may significantly reduce or avoid delay time and energy consumption due to data movement.

Unlike the memory system 310, the host memory 306 can be used for in-memory processing of the host CPU 304. In-memory processing can store as much data as possible in the host memory 306 and reduce the delay time due to disk I/O (e.g., I/O of the memory system). The host memory 306 under this scheme could support great performance in database work, real-time analysis, etc. However, because the host memory 306 is expensive and has limited capacity, there may be limitations in processing very large data sets. Thus, the data processing apparatus can overcome some limitations of operation and performance of the host memory 306 through the memory system 310 including the controller 312 for the near data processing (NDP).

As above described, according to an embodiment of the present disclosure, a memory device or a memory system can improve data input/output performance of a memory device or a memory system through scheduling for efficiently transmitting a plurality of multi-clock commands while satisfying a minimum burst period or a minimum column command delay period (e.g., Column to Column Delay, tCCD).

In addition, according to an embodiment of the present invention, a memory device or a memory system can improve data input/output performance of a memory device or a memory system through a scheduling device and an operation method that change the transmission order of a plurality of commands transmitted adjacently according to types of the commands. Such a scheduling device and an operation method have the advantages of less consumption of resources for scheduling and less delay in operations due to scheduling.

The methods, processes, and/or operations described herein may be performed by code or instructions to be executed by a computer, processor, controller, or other signal processing device. The computer, processor, controller, or other signal processing device may be those described herein or one(s) in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the invention has been illustrated and described with respect to the specific embodiments, it will be apparent to those skilled in the art in light of the present disclosure that various changes and modifications may be made without departing from the spirit and scope of the present disclosure as defined in the following claims. Furthermore, the embodiments may be combined to form additional embodiments.

What is claimed is:

1. A memory system, comprising:
a memory device including at least one data storage area; and
a memory controller coupled to the memory device and configured to transmit at least one command, scheduled to be transmitted within a preset clock range, to the memory device,
wherein the memory controller is configured to transmit an activation command included in the at least one command to the memory device when a command to be transmitted subsequent to the activation command is not a data input and output (input/output) command.

2. The memory system according to claim 1, wherein the data input/output command comprises at least one of a read command and a write command, and
wherein the memory controller is configured to transmit the data input/output command to the memory device prior to the activation command when the command to be transmitted subsequent to the activation command is the data input/output command.

3. The memory system according to claim 1, wherein the activation command and the data input/output command are multi-clock commands to be transmitted during plural clock cycles.

4. The memory system according to claim 1, wherein the preset clock range comprises at least four clock cycles.

5. The memory system according to claim 1, wherein the at least one command comprises a precharge command, wherein the precharge command is a single-clock command that is transmitted during a single clock cycle, and
wherein the controller is configured to transmit the precharge command to the memory device regardless of a transmission order of the data input/output command.

6. The memory system according to claim 1, wherein the memory controller is configured to transmit the data input/output command to the memory device before the activation command when a command transmitted subsequent to the data input/output command is the activation command.

7. The memory system according to claim 1, wherein the at least one data storage area comprises a plurality of memory banks, and
wherein the activation command and the data input/output command are transmitted to different banks among the plurality of memory banks.

8. The memory system according to claim 1, wherein the data input/output command has a minimum burst period or a minimum column command delay period which is longer than the preset clock range.

9. The memory system according to claim 8, wherein the minimum column command delay period comprises eight clock cycles.

10. A method for operating a memory system, comprising:
determining at least one command scheduled to be transmitted within a preset clock range to a memory device comprising at least one data storage area; and
transmitting, to the memory device, an activation command included in the at least one command when a command to be transmitted subsequent to the activation command is not a data input and output (input/output) command.

11. The method according to claim 10, further comprising:
transmitting the data input/output command included in the at least one command to the memory device prior to the activation command when the command to be transmitted subsequent to the activation command is the data input/output command.

12. The method according to claim 10, wherein the data input/output command comprises at least one of a read command and a write command.

13. The method according to claim 10, wherein the activation command and the data input/output command are multi-clock commands to be transmitted during plural clock cycles.

14. The method according to claim 10, wherein the preset clock range comprises at least four clock cycles.

15. The method according to claim 10, wherein the at least one command comprises a precharge command, wherein the precharge command is a single-clock command transmitted during a single clock cycle, and
wherein the method further comprises transmitting the precharge command to the memory device regardless of a transmission order of the data input/output command.

16. The method according to claim 10, wherein the at least one data storage area comprises a plurality of memory banks, and
wherein the activation command and the data input/output command are transmitted to different banks among the plurality of memory banks.

17. The method according to claim 10, wherein the data input/output command has a minimum burst period or a minimum column command delay period which is longer than the preset clock range.

18. The method according to claim 17, wherein the minimum column command delay period comprises 8 clock cycles.

19. A command scheduler coupled to a memory device comprising at least one data storage area, wherein the command scheduler is configured to determine a transmission timing of at least one command scheduled to be transmitted within a preset clock range, wherein the command scheduler is configured to transmit an activation command included in the at least one command to the memory device when a command transmitted following the activation command is not a data input and output (input/output) command.

20. The command scheduler according to claim 19, wherein the activation command and the data input/output command are multi-clock commands transmitted during plural clock cycles, and
wherein the data input/output command comprises at least one of a read command and a write command.
